(19) United States
(12) Patent Application Publication
(10) Pub. No.: US 2020/0004013 A1
(43) Pub. Date: Jan. 2, 2020

(54) LIGHT HOMOGENIZING ELEMENTS WITH CORRECTIVE FEATURES

(71) Applicant: CORNING INCORPORATED, CORNING, NY (US)

(72) Inventors: Joshua Monroe Cobb, Victor, NY (US); Paul Francis Michaloski, Rochester, NY (US); Daniel Max Staloff, Rochester, NY (US)

(21) Appl. No.: 16/433,285

(22) Filed: Jun. 6, 2019

Related U.S. Application Data
(60) Provisional application No. 62/690,398, filed on Jun. 27, 2018.

(51) Int. Cl. G02B 27/00; G02B 3/00; G03F 7/20

(52) U.S. Cl. CPC G02B 27/0025; G03F 7/7015; G02B 3/0006

(57) ABSTRACT

Light homogenizing elements are described. The light homogenizing elements include lens arrays with corrective features designed to improve the uniformity of light fields produced by optical sources. The corrective features include masks placed at selected positions of selected lenslets in a lens array. The corrective features block or reduce the transmission of light through the lens array at the selected position to correct for spatial or angular non-uniformities in a light field produced by an optical source. Illumination systems that include a corrected lens array coupled to a light source produce highly uniform light fields. Applications include microlithography.

This application claims the benefit of priority to U.S. Provisional Application Ser. No. 62/690,398 filed on Jun. 27, 2018, the content of which is relied upon and incorporated herein by reference in its entirety.

### FIELD

This disclosure relates to light homogenizing elements for illumination systems. More particularly, this disclosure relates to light homogenizing elements that deliver a highly uniform distribution of light at an image plane of an illumination systems. Most particularly, this disclosure relates to light homogenizing elements that include a lens array with a plurality of lenslets in which an aperture of at least one lenslet is masked to correct for non-uniformities in the light field incident to the lens array.

### BACKGROUND

Projection systems, and microlithography projection systems, in particular, require a uniform field of electro-magnetic energy to illuminate an object such as a mask or spatial light modulator. This energy is then transferred by an optical system to illuminate a wafer or create an image in some other location. If the field is not uniform the exposure of the image will not be uniform.

Many current microlithography illuminators use a low-pressure mercury arc lamp to generate 365 nm light. The large lamps and their associated utilities are expensive, inefficient, and can cause potential safety problems. Moving from a lamp source to a light emitting diode (LED) source makes improvements on all of these fronts. These LEDs can be placed in an array and homogenized to create a uniform field of light at the reticle plane. The LED dies are made in a semiconductor manufacturing process, which results in repeatable structures and patterns for making the die.

There are several possible methods of uniformizing the LEDs. The two most efficient methods are with a pair of lens arrays or a kaleidoscope, also known as a light tunnel or integrating bar. Each method has advantages and disadvantages. A disadvantage to a lens array solution is that odd order non-uniformities cannot be uniformized in a lens array solution. There are also manufacturing variations that can create subtle and slight variations in the uniformity that cannot be compensated for in traditional lens array or light tunnel illuminators. For example, variations in coatings on lens elements will change the transmission as a function of the field, and this has an impact on the final uniformity. Microlithography systems, in particular, have extremely tight tolerances on the uniformity of the light field so that microelectronic circuitry is printed consistently on the wafer.

If an array of LEDs is used as a source and all LEDs are oriented in the same clocking position, a tilt to the irradiance pattern will be presented to the illumination system. Since the tilt is an odd function, the lens array cannot correct the non-uniformity. It can be minimized by creating a lens array with smaller and more lens elements, but this approach can be very expensive and difficult to manufacture. If a more conventional source is used, there are still non-uniformities created by imperfections in the illumination system. One method that also has been used to correct non-uniformities is use of an optical apodizer. An optical apodizer is a window with a variable coating that is placed just before the uniform plane. The variable coating has a variable transmission function that reduces transmission in high energy areas to create a more uniform light field. These optical apodizers are difficult and expensive to make, and are usually used only to correct rotationally symmetric non-uniformities.

Therefore, there is a need for a low-cost method for fixing residual non-uniformities in light fields caused by light source anomalies or manufacturing variations in projection illumination systems.

### SUMMARY

Light homogenizing elements are described. The light homogenizing elements include lens arrays with corrective features designed to improve the uniformity of light fields produced by optical sources. The corrective features include masks placed at selected positions of selected lenslets in a lens array. The corrective features block or reduce the transmission of light through the lens array at the selected position to correct for spatial or angular non-uniformities in a light field produced by an optical source. The light field exiting the corrected lens array has greater uniformity than the light field entering the lens array. Preferred lens arrays include fly's eye arrays. Illumination systems that include a corrected lens array coupled to a light source produce highly uniform light fields. Applications include microlithography.

The present disclosure extends to:
A light homogenizing element comprising:
   a lens array configured to transmit light at an operating wavelength, the lens array comprising a plurality of lenslets, the plurality of lenslets including a first lenslet, the first lenslet having a first aperture, the first aperture having a surface with a corrected portion defined by a first corrective feature, the first corrective feature reducing a transmittance of the operating wavelength through the first lenslet.

The present disclosure extends to:
A light illumination system comprising:
   a light source;
   a first lens array operatively coupled to the light source, the first lens array configured to transmit light at an operating wavelength, the first lens array comprising a plurality of lenslets, the plurality of lenslets including a first lenslet, the first lenslet having a first aperture, the first aperture having a surface with a corrected portion defined by a first corrective feature, the first corrective feature reducing a transmittance of the operating wavelength through the first lenslet.

The present disclosure extends to:
A method of correcting an illumination system comprising:
   producing a light field at an image plane of an illumination system, the illumination system comprising a light source producing light at an operating wavelength, the light source operatively coupled to a first lens array, the first lens array comprising a plurality of lenslets, the plurality of lenslets including a first lenslet and a second lenslet, the first lenslet having a first aperture and the second lenslet having a second aperture;
   determining a uniformity of the light field at the image plane by measuring the irradiance of the light field at a plurality of locations in the image plane; and
   improving the uniformity of the light field, the improving including modifying the first lenslet to include a first corrective feature, the first corrective feature defining a first corrected portion of the first aperture and reducing a transmittance of the operating wavelength through the first lenslet.

### BRIEF DESCRIPTION OF THE DRAWINGS

FIG. 1 shows a lens array with lenslets having a square cross-section, a powered surface and a plano surface.

FIG. 2 shows a lens array with lenslets having a round cross-section, a powered surface and a plano surface.

FIG. 3 shows a lens array with lenslets having a polygonal cross-section, a powered surface and a plano surface

FIG. 4 shows an illumination system that includes two fly's eye arrays.

FIG. 5 shows a two-dimensional representation of an uncorrected lens array.

FIG. 6 shows a two-dimensional representation of a corrected lens array

FIG. 7 shows a two-dimensional representation of a corrected lens array

FIG. 8 shows perforated corrective features.

FIG. 9 shows two regions of an image plane.

FIG. 10 shows the pupil at an image plane of an illumination system with an uncorrected lens array.

FIG. 11 shows the pupil at an image plane of an illumination system with a lens array having two corrective features.

FIG. 12 shows the pupil at an image plane of an illumination system with a lens array having two corrective features.

FIG. 13 shows a flowchart for calculating properties of a corrective feature.

### DETAILED DESCRIPTION OF THE ILLUSTRATED EMBODIMENTS

Microlithography is a widely used process in the patterning of silicon wafers in the semiconductor industry. In microlithography, a pattern on a reticle is transferred to a photoresist on a wafer to define a pattern for a microelectronic circuit. The apparatus used to perform microlithography includes an illumination system and a projection system. The illumination system includes a light source and an optical system. The optical system produces a light field from the light source and directs it to the reticle. A surface of the reticle includes features that modify the light field (e.g. through diffraction) to produce a patterned light field. The patterned light field is directed to the projection system, which includes optical elements that direct the patterned light field to a photoresist. The pattern of the light field determines the areas of the photoresist that are exposed to the light field. Subsequent development of the photoresist creates a contrast between exposed and unexposed areas to define a pattern for a microelectronic circuit.

As features sizes for microelectronic circuits decrease, there is a need for greater precision in the microlithography process. Spatial and angular uniformity of the light field incident to the reticle surface is critical to achieving faithful transfer of the reticle pattern to the wafer. Variability in the output of the light source is a significant contributor to non-uniformities in the light field produced by the illumination system. Light sources used in illumination systems include lamps, light emitting diodes, and lasers. Variabilities in light sources include spatial and angular deviations in the light field. Spatial deviations correspond to non-uniformity in the intensity or power of the light field over the cross-section of the light field and angular deviations refer to non-uniformities in divergence of the light field over the cross-section of the light field. Manufacturing variability or imperfections in other optical elements present in the illumination system and alignment errors also contribute to non-uniformities in the light field. Non-uniformities in the light field are replicated at the reticle and ultimately transferred to the photoresist to create imperfections in the patterned microelectronic circuit formed on the wafer.

One strategy for improving the uniformity of the light field of an illumination system is to incorporate a light homogenizing element in the optical system. The light homogenizing element is operatively coupled to the light source of the illumination system. Light produced by the light source is directed to the light homogenizing element. Light enters the light homogenizing element at one or more apertures, passes through the light homogenizing element, and exits the light homogenizing element. Light homogenizing elements are optical elements that suppress variability in a light field by mixing light rays that deviate in space or angle to provide a homogenized light field with averaged spatial and angular characteristics having greater uniformity. Common light homogenizing elements include integrator rods and lens arrays. Illumination systems with light homogenizing elements provide light fields with greater uniformity. There remains, however, a need for further improvements in the uniformity of light fields produced by illumination systems. As used herein, “uniformity” of a light field refers to uniformity in irradiance at an imaging field plane, where irradiance is defined as power per unit area and is typically expressed in units of mW/cm².

The present disclosure is directed to lens arrays with improved performance. A lens array is an optical element that consists of a two-dimensional array of lenses. The individual lenses of a lens array are referred to herein as lenslets. The surfaces through which light enters and exits a lenslet are referred to herein as apertures. The lenslets are integrated to form a monolithic lens array. A monolithic lens array can be formed from a single substrate (e.g. piece of glass) through selective removal of material to form the individual lenslets in an intended pattern or configuration. Alternatively, the individual lenslets can be formed separately and combined (e.g. fused) into a monolithic assembly. Embodiments of lens arrays include fly's eye arrays. Lens arrays are designed to transmit a single wavelength, multiple wavelength, or over a continuous range of wavelengths. The wavelength(s) transmitted by a lens array are referred to herein as the operating wavelength(s) of the lens array. Representative operating wavelengths include infrared (750 nm-2000 nm), visible (400 nm-750 nm), and ultraviolet wavelengths (100 nm-400 nm). Lens arrays are constructed of materials suitable for transmitting operating wavelength(s) needed for a particular application. Representative materials for lens arrays include glass, silica glass, doped silica glass, and fluoride crystals. Fluoride crystals include CaF₂ and MgF₂.

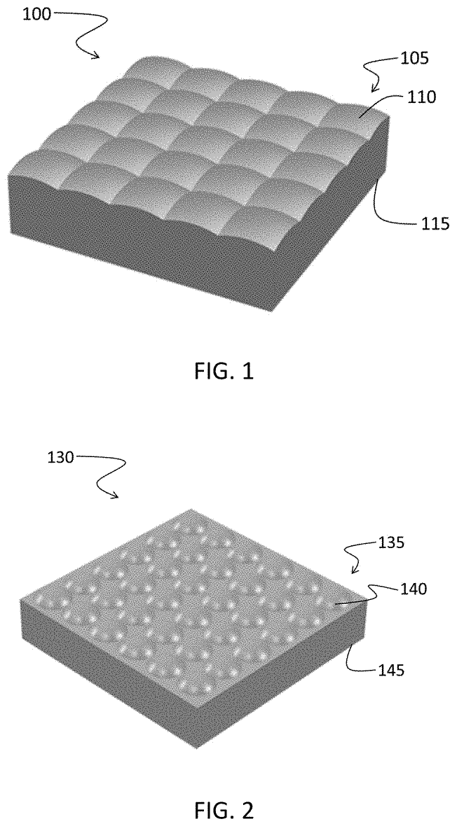

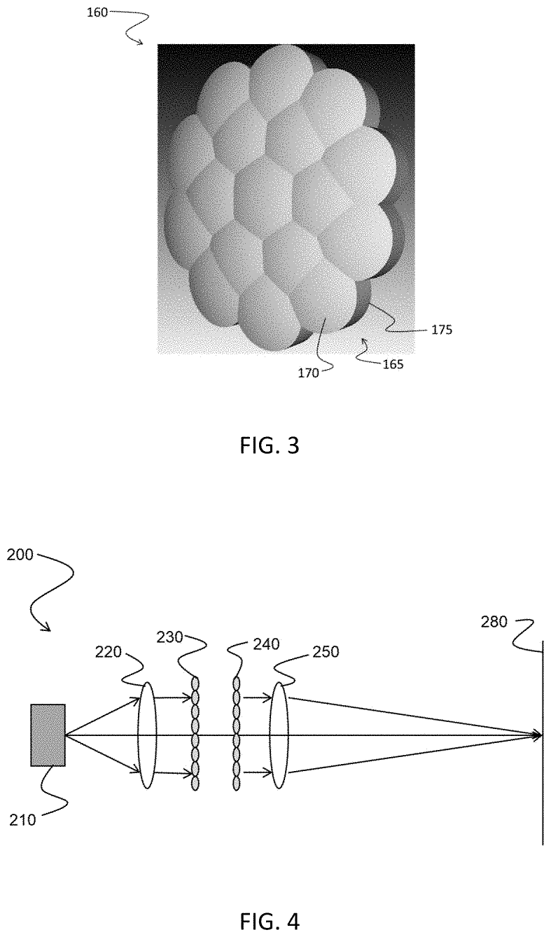

FIGS. 1-3 show representative lens arrays 100, 130, and 160. Lens array 100 includes a plurality of lenslets 105 with opposing apertures 110 and 115. Lenslet 105 has a square cross-section, aperture 110 is powered, and aperture 115 is plano. Lens array 130 includes a plurality of lenslets 135 with opposing apertures 140 and 155. Lenslet 135 has a round cross-section, aperture 140 is powered, and aperture 145 is plano. Lens array 160 includes a plurality of lenslets 165 with opposing apertures 170 and 175. Lenslet 165 has a polygonal cross-section, aperture 170 is powered, and aperture 175 is plano.

In various aspects, the cross-section of lenslets is square, rectangular, circular, elliptical, oval, round, or polygonal (e.g. hexagonal). The shape of the lenslet determines the shape of the light field and is selected according to the intended application of an illumination system. The lenslet apertures have surfaces that are powered or plano. Powered apertures have surfaces that are concave, convex, spherical, aspherical, or anamorphic. Opposing apertures of a lenslet are the same or different in shape or power. In various aspects, opposing apertures of a lenslet are both plano, both powered, or a combination of powered and plano. In one embodiment, the lens array is a fly's eye array.

In one embodiment, the illumination system includes two or more lens arrays. FIG. 4, for example, illustrates an illumination system having two lens arrays. Illumination system 200 includes light source 210, condenser lens 220, lens array 230, lens array 240, and combining lens 250. Light source 210, condenser lens 220, lens array 230, lens array 240, and combining lens 250 are operative coupled to each other along an optical path extending from light source 210 to homogenization plane 280. Lens array 230 receives a light beam from condenser lens 220 and divides it into multiple beamlets. Lens array 240 acts in combination with combining lens 250 to superimpose the images of each of the beamlets at homogenization plane 280. The light field at homogenization plane 280 has is more uniform than the light field emanating from light source 210. In a microlithography apparatus, the uniform light field at homogenization plane 280 is directed to a reticle for pattern transfer to a wafer.

In one embodiment, lens array 230 is conjugate to homogenization plane 280 and lens array 240 is conjugate to the pupil of the illumination system. In a preferred embodiment, lens arrays 230 and 240 are equivalent. The light source 210 is imaged by condenser lens 220 and lens array 230 so that the aperture of each lenslet in lens array 240 is filled by an image of light source 210. The aperture of each lenslet of lens array 230 is magnified and imaged to homogenization plane 280. The irradiance at homogenization plane 280 is the summation of the energy from all lenslets of lens array 230. Since the images of the lenslets are superimposed, a highly uniform distribution of irradiance is created.

The distribution of irradiance at homogenization plane 280 has an average irradiance, a maximum irradiance and a minimum irradiance. Uniformity of the distribution of irradiance is assessed as a difference between the maximum irradiance and the minimum irradiance. The difference between the maximum irradiance and the minimum irradiance is less than 20% of the average irradiance, or less than 10% of the average irradiance, or less than 5% of the average irradiance, or less than 1% of the average irradiance.

In the example depicted in FIG. 4, lens arrays 230 and 240 are made from silica glass and include an 11×11 array of lenslets. The lenslets have one aperture with a powered surface (radius=63.81 mm), one aperture with a plano surface, and a square cross-section (side length=23.454 mm). The spacing between lens arrays 230 and 240 is approximately one focal length of a lenslet.

Although improved light field uniformity results from inclusion of one or more lenses in the optical path of an illumination system, further improvements are needed. As noted above, manufacturing variability and imperfections in optical components (e.g. condenser lens 220 and combiner lens 250) introduce localized non-uniformities that are difficult to correct. Further complications arise from variabilities in the light source. In the limit of a light source that is uniform both spatially and angularly, no correction of non-uniformities in the light field is required. Actual light sources, however, are not uniform in space and angle. Lamps have filaments that extend over distances of millimeters or centimeters and variability in the composition, durability, or power distribution over the length leads to variabilities in the light field produced. LEDs also have finite light-generating areas that are subject to variability. Similarly, laser light is not perfectly collimated and exhibits variability in divergence and uniformity (angular and spatial). Non-uniformities in the light field produced by an optical source become more pronounced when multiple light devices are combined and integrated. To achieve higher irradiance, for example, it is common to bundle LEDs to form an LED array and to use the LED array as a light source in an optical system. Manufacturing variability in the production of LEDs leads to differences in the characteristics of the individual LEDs in an array. There may also be systematic non-uniformities in the irradiance distribution of the LED dies. Variability in operating conditions (e.g. fluctuations in the delivery of power or irregularities in supporting electronic components) also lead to differences in the characteristics of the individual LEDs in an array. The light field produced by an LED array exhibits non-uniformities due to differences in light fields generated by the individual LEDs in an array, or similar non-uniformities in each LED, and these non-uniformities are a function of position in the LED array. Such non-uniformities are difficult to correct and are specific to a particular LED array. If, for example, an LED array reaches its operating lifetime and needs to be replaced, the replacement LED array will likely produce a light field with non-uniformities that differ in degree, type, and spatial position than the non-uniformities in the light field produced by the original LED array. Such variations require significant and expensive adjustments in downstream optical elements to effect corrections.

The present disclosure provides lens arrays with corrective features designed to further improve the uniformity of light fields in optical systems. The corrective features are selectively placed at localized positions within a lens array to compensate for localized non-uniformities in light field. The corrective features are preferably features placed on or near the surface of an aperture of one or more lenslets of a lens array, where the surface features reduce transmission through the lenslet. In one embodiment, the corrective features are in direct contact with the surface of the aperture. In a preferred embodiment, the corrective features are spaced apart from the surface of the aperture and positioned in close proximity to the surface of the aperture. In this embodiment, a gap is present between the corrective feature and the surface of the aperture, but the corrective feature is positioned sufficiently close to the surface of the aperture to reduce transmittance through the lenslet. Mechanical mounts are used to position corrective features in close proximity to the surface of an aperture. In one embodiment, the corrected portion of an aperture or a surface is a shadow of a corrective feature positioned in close proximity to the aperture or surface.

A lenslet with a corrective feature is referred to herein as a corrected lenslet, the portion of a lenslet or lens array covered by the corrective feature is referred to herein as the corrected portion of the lenslet or lens array, and a lens array with at least one corrected lenslet is referred to herein as a corrected lens array. An aperture or surface having a corrective feature is referred to herein as a corrected aperture or corrected surface, respectively. When the corrective feature is a mask, the terms masked lenslet, masked lens assembly, and masked portions are also used herein. A lenslet lacking a corrective feature is referred to herein as an uncorrected lenslet. Portions of a lenslet or lens array lacking a corrective feature are referred to herein as uncorrected portions. An aperture or surface lacking a corrective feature is referred to herein as a corrected aperture or corrected surface, respectively. The lens array includes one or a plurality of corrected lenslets. The lens array optionally also includes one or a plurality of uncorrected lenslets.

The corrected portion is defined by the corrective feature. When the corrective feature is in direct contact with a lenslet, the corrected portion of the lenslet coincides with the corrective feature. When the corrective feature is spaced apart from the lenslet, the corrected portion of the lenslet comprises or coincides with a shadow of the corrective feature on the surface of an aperture of the lenslet.

In one embodiment, the corrective features are masks made from a material that is opaque or partially opaque to the wavelength(s) of light passing through the lens array. The opaque material absorbs and/or reflects the wavelength(s) of light passing through the lens array to reduce transmittance. Representative materials for masks include metals (e.g. aluminum or stainless steel) and transparent substrates coated with an interference coating designed to reduce transmittance to a controlled degree. As used herein, a transparent substrate is a substrate with at least 90%/mm transmittance at an operating wavelength. In one embodiment, the mask is perforated and includes a hole or pattern of holes to permit partial transmittance of the light field through the mask. The holes are arranged randomly or in a pattern in a surrounding material. The surrounding material is opaque or translucent. The holes are uniform in size or variable in size. In another embodiment, the mask is made from a material translucent to the operating wavelength of the lens array.

The thickness, configuration, and/or composition of the mask material is selected to block light passing through the corrected portion of the lens array (0% transmittance) or to reduce transmittance through the corrected portion relative to uncorrected portions to a controlled degree. Transmittance of the operating wavelength(s) through a corrected portion of a lens array is less than 50%, or less than 30%, or less than 10%, or less than 5%, or less than 1% of the transmittance of the operating wavelength(s) through uncorrected portions of the lens array. Transmittance of the operating wavelength(s) through uncorrected portion of the lens array is greater than 80%/mm, or greater than 90%/mm, or greater than 95%/mm, where mm refers to millimeter of distance in the direction of propagation of the operating wavelength(s) through the lens array. The location of the masks is selected to regulate transmittance through the lens array and to compensate for localized variations in intensity or irradiance across the light field. Spatial and angular non-uniformities are correctable with the present lens arrays.

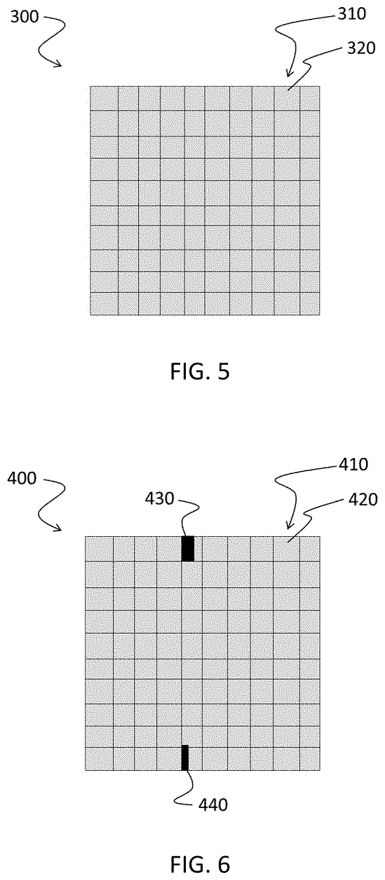

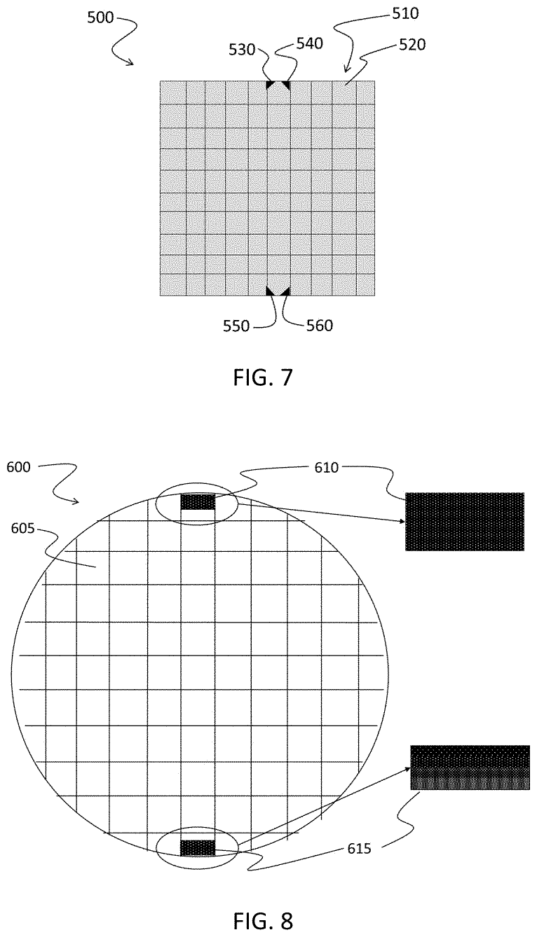

The corrective features at least partially cover at least one aperture of at least one lenslet in a lens array. The corrective feature is placed at or near the aperture of a lenslet. FIG. 5 shows a schematic two-dimensional representation of an uncorrected lens array. Lens array 300 includes a plurality of lenslets 310 having apertures 320. Lens array 300 lacks corrective features. FIGS. 6 and 7 show examples of corrected versions of the lens array shown in FIG. 5. Corrected lens array 400 includes a plurality of lenslets 410 having apertures 420. Corrected lens array 400 further includes corrective features 430 and 440 that are positioned at two of the plurality of lenslets 410. Corrective features 430 and 440 partially cover the lenslets to differing degrees and are masks that block or reduce transmission of light those lenslets. The distribution of light through corrected lens array 400 is accordingly modified or refined. Corrected lens array 500 includes a plurality of lenslets 510 having apertures 520. Corrected lens array 500 further includes corrective features 530, 540, 550 and 560 that are positioned at two of the plurality of lenslets 510. Corrective features 530, 540, 550, and 560 partially cover the lenslets at corner locations and are masks that block or reduce transmission of light at the corner positions of those lenslets. The distribution of light through corrected lens array 500 is accordingly modified or refined.

FIG. 8 shows an example of a corrected lens array that includes corrective features in the form of perforated masks. Lens array 600 includes lenslets 605 and corrective features 610 and 615. Corrective features 610 and 615 are shown at particular positions in lens array 600 and are enlarged to show the structure in more detail. Corrective feature 610 is a perforated mask having a pattern of holes. The holes are uniform in size and arranged in a periodic pattern. The holes permit partial transmittance of light through corrective feature 610. Corrective feature 615 is a perforated mask that includes holes of variable size.

Although the lens arrays depicted in FIGS. 5-8 include lenslets having square cross-sections and plano surfaces, the principles illustrated and formation of corrective features described applies generally to lens arrays, including fly's eye arrays, having lenslets of any cross-sectional shape and/or any state of aperture power (powered or plano surface).

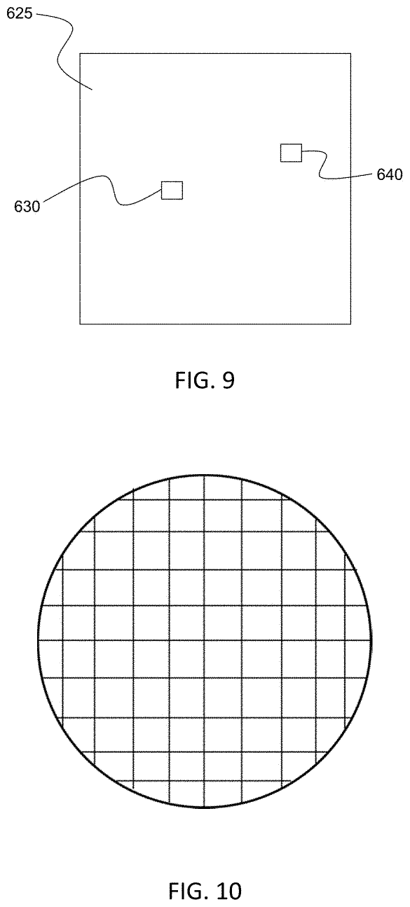

FIG. 9 illustrates a light field at an imaging plane 625 FIG. 9 shows representative regions 630 and 640 of the light field in the imaging plane. For purposes of uniformity of the light field, it is desirable for the irradiance at region 630 to be the same as the irradiance at region 640. For reasons noted above, however, the irradiances at regions 630 and 640 may differ. If the irradiances at regions 630 and 640 differ, a correction in the light field is required. If, for example, region 640 has a higher irradiance than region 630, it would be desirable to reduce the irradiance of region 640 without affecting the irradiance at region 630. The corrective features described herein reduce the irradiance of light transmitted through a corrected portion of a lens array without affecting the irradiance of light transmitted through the remainder of the lens array. The corrective features selectively reduce irradiance corrected portions of the lens array, thereby permitting control over irradiance at a corresponding position in an imaging plane.

By way of example and referring to FIG. 4, homogenization plane 280 is an imaging plane at which high uniformity is desired and corrected lens array 400 shown in FIG. 6 is incorporated in illumination system 200 as lens array 230. The function of corrective feature 430 is to reduce irradiance in a selected portion of the light field entering lens array 230 without affecting irradiance in other portions of the light field.

Lens array 240 is conjugate to the pupil of the illumination system 200. The pupil is the angular distribution of the energy as it focuses onto homogenization plane 280. In some applications, the centroid of the angular distribution is important. Modification of lens array 230 with a corrective feature can change the centroid of the angular distribution of the light field at homogenization plane 280. The variation of the centroid of the angular distribution accompanying a modification of lens array 230 with a corrective feature can be reduced by including a corrective feature complementary to corrective feature 430 with lens array 230. The complementary corrective feature is located at a position opposite to corrective feature 430 and acts to reduce irradiance from the opposite side of the light field entering lens array 400. Corrective feature 440 is complementary to corrective feature 430. The reduction of irradiance by corrective feature 440 counteracts the variation of angular centroid caused by corrective feature 430 to maintain a centroid position at homogenization plane 280 that closely approximates the centroid of the light field incident to lens array 400. The complementary corrective feature has the same or different shape or transmittance than the corrective feature. As defined herein, a complementary corrective feature is a feature that fully or partially compensates for variation in the centroid of the angular distribution of the light field resulting from a corrective feature. In one embodiment, the positions of the corrective feature and its complement are symmetric about the center of the pupil or symmetric about the center of lens array 240.

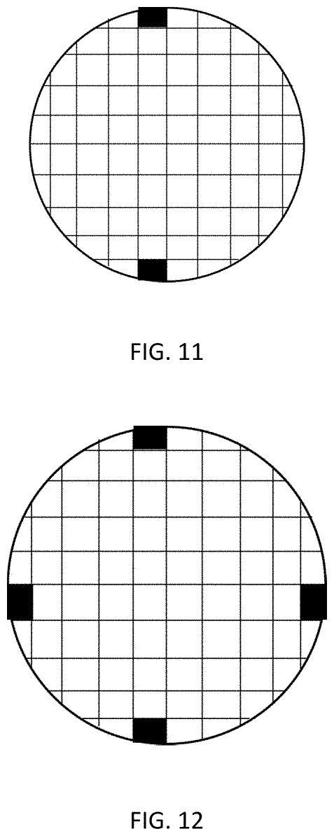

To further illustrate in reference to FIG. 4, FIG. 10 shows the pupil at homogenization plane 280 when lens array 230 is uncorrected. The pupil is an image of the light field at lens array 240, which is determined by the light field at lens array 230. Correction of lens array 230 leads to modification of the light field at the pupil. FIG. 11, for example, shows the pupil when opposing corrective features are included at upper and lower lenslets of lens array 230. The dark spots correspond to regions of the light field at the pupil having reduced irradiance. Reduction of irradiance at symmetric positions at the pupil minimizes variation in the centroid of the light field so that the centroid of the pupil has minimal variation across homogenization plane 280. FIG. 12 illustrates an example of the pupil of the light field when corrective features are incorporated at four lenslets of lens array 230. The four corrective features are arranged as two pairs of opposing corrective features. Each corrective feature of a pair counteracts the effect of the other corrective feature of the pair on the centroid.

Processes for adding corrective features to form corrected lenslets include designing a mask (perforated or unperforated) having a particular size, shape, and coating, and mechanically mounting the mask in close proximity to an aperture at a predetermined location of a lens array to enable correction of the light field passing through the aperture. This process can be repeated for each lenslet for which correction is desired. Interference films configured to reduce the transmittance of an operating wavelength can be formed on transparent substrates using materials and techniques known in the art (e.g. PVD, CVD).

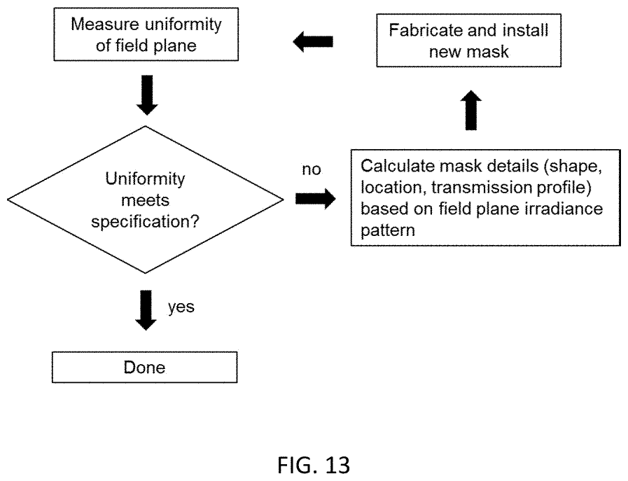

To determine placement of corrective features, one can assemble the optical system, characterize the uniformity of the light field at a particular point along the optical pathway, determine the positions in the light field requiring correction, and correspondingly place corrective features at selected positions of the lens array to compensate for non-uniformities. In FIG. 4, for example, one can characterize the light field at homogenization plane 280 to determine the state of uniformity of the light field and to identify positions within the light field requiring correction. Compensating corrective features can then be placed near or on the aperture(s) of selected lenslet(s) of lens array 230. Uniformity of the light field can then be assessed again and the process of applying corrective features to lens arrays 230 and/or 240 can be repeated iteratively to achieve the degree of uniformity in the light field needed for a particular application. FIG. 13 shows a flowchart for a method of determining the configuration of a corrective feature.

Aspect 1 of the description is:
A light homogenizing element comprising:
   a lens array configured to transmit light at an operating wavelength, the lens array comprising a plurality of lenslets, the plurality of lenslets including a first lenslet, the first lenslet having a first aperture, the first aperture having a surface with a corrected portion defined by a first corrective feature, the first corrective feature reducing a transmittance of the operating wavelength through the first lenslet.

Aspect 2 of the description is:
The light homogenizing element of aspect 1, wherein the operating wavelength is an ultraviolet wavelength.

Aspect 3 of the description is:
The light homogenizing element of aspect 1 or 2, wherein each of the plurality of lenslets has a square cross-section.

Aspect 4 of the description is:
The light homogenizing element of any of aspects 1-3, wherein the surface of the first aperture is powered.

Aspect 5 of the description is:
The light homogenizing element of any of aspects 1-4, wherein the first corrective feature partially covers the surface of the first aperture.

Aspect 6 of the description is:
The light homogenizing element of any of aspects 1-5, wherein the first corrective feature is spaced apart from the surface of the first aperture.

Aspect 7 of the description is:
The light homogenizing element of any of aspects 1-6, wherein the first corrective feature is a mask.

Aspect 8 of the description is:
The light homogenizing element of aspect 7, wherein the mask comprises stainless steel or aluminum.

Aspect 9 of the description is:
The light homogenizing element of aspect 7 or 8, wherein the corrective portion comprises a shadow of the mask.

Aspect 10 of the description is:
The light homogenizing element of any of aspects 7-9, wherein the mask is perforated.

Aspect 11 of the description is:
The light homogenizing element of any of aspects 1-7, wherein the first corrective feature is translucent.

Aspect 12 of the description is:
The light homogenizing element of any of aspects 1-7, wherein the first corrective feature comprises a transparent substrate coated with an interference coating.

Aspect 13 of the description is:
The light homogenizing element of any of aspects 1-7, wherein the first corrected lenslet has a second aperture, the second aperture having an uncorrected surface.

Aspect 14 of the description is:
The light homogenizing element of any of aspects 1-13, wherein the plurality of lenslets further includes a second lenslet, the second lenslet having a second aperture, the second aperture having a surface with a corrected portion defined by a second corrective feature, the second corrective feature reducing a transmittance of the operating wavelength through the second lenslet.

Aspect 15 of the description is:
The light homogenizing element of aspect 14, wherein the second corrective feature is complementary to the first corrective feature.

Aspect 16 of the description is:
The light homogenizing element of any of aspects 1-15, wherein the transmittance of the operating wavelength through the corrected portion of the first aperture is 0%.

Aspect 17 of the description is:
The light homogenizing element of any of aspects 1-16, wherein the first aperture further includes an uncorrected portion.

Aspect 18 of the description is:
The light homogenizing element of aspect 17, wherein the transmittance of the operating wavelength through the corrected portion is less than 10% of the transmittance of the operating wavelength through the uncorrected portion.

Aspect 19 of the description is:
A light illumination system comprising:
   a light source;
   a first lens array operatively coupled to the light source, the first lens array configured to transmit light at an operating wavelength, the first lens array comprising a plurality of lenslets, the plurality of lenslets including a first lenslet, the first lenslet having a first aperture, the first aperture having a surface with a corrected portion defined by a first corrective feature, the first corrective feature reducing a transmittance of the operating wavelength through the first lenslet.

Aspect 20 of the description is:
The light illumination system of aspect 19, wherein the light source comprises a plurality of light emitting diodes.

Aspect 21 of the description is:
The light illumination system of aspect 19 or 20, further comprising a second lens array operatively coupled to the first lens array, the second lens array lacking a corrective feature.

Aspect 22 of the description is:
The light illumination system of aspect 21, wherein the first lens array is positioned between the light source and the second lens array.

Aspect 23 of the description is:
The light illumination system of any of aspects 19-22, wherein the light illumination system produces a light field at an imaging plane, the light field having a distribution of irradiance in the imaging plane, the distribution having an average irradiance, a maximum irradiance and a minimum irradiance; and wherein the maximum irradiance differs from the minimum irradiance by less than 10% of the average irradiance.

Aspect 24 of the description is:
The light illumination system of aspect 22 or 23, wherein the first lens array and the second lens array are separated by approximately a focal length of the first lenslet.

Aspect 25 of the description is:
The light illumination system of any of aspects 22-24, wherein the plurality of lenslets further includes a second lenslet, the second lenslet having a second aperture, the second aperture having a surface with a corrected portion defined by a second corrective feature, the second corrective feature reducing a transmittance of the operating wavelength through the second lenslet.

Aspect 26 of the description is:
The light illumination system of aspect 25, wherein the first corrective feature and the second corrective feature are symmetrically disposed about the center of a pupil of the light illumination system.

Aspect 27 of the description is:
A method of correcting an illumination system comprising:
   producing a light field at an image plane of an illumination system, the illumination system comprising a light source producing light at an operating wavelength, the light source operatively coupled to a first lens array, the first lens array comprising a plurality of lenslets, the plurality of lenslets including a first lenslet and a second lenslet, the first lenslet having a first aperture and the second lenslet having a second aperture;
   determining a uniformity of the light field at the image plane by measuring the irradiance of the light field at a plurality of locations in the image plane; and
   improving the uniformity of the light field, the improving including modifying the first lenslet to include a first corrective feature, the first corrective feature defining a first corrected portion of the first aperture and reducing a transmittance of the operating wavelength through the first lenslet.

Aspect 28 of the description is:
The method of aspect 27, wherein the plurality of locations includes a first location and a second location; and wherein the first corrective feature reduces the irradiance at the first location and not at the second location.

Aspect 29 of the description is:
The method of aspect 27 or 28, wherein the distribution of irradiance including a maximum irradiance and a minimum irradiance and the improving includes reducing the difference between the maximum irradiance and the minimum irradiance.

Aspect 30 of the description is:
The method of any of aspects 27-29, further comprising modifying the first lenslet to include a second corrective feature, the second corrective feature defining a second corrected portion of the first aperture and further reducing the transmittance of the operating wavelength through the first lenslet.

Aspect 31 of the description is:
The method of any of aspects 27-30, further comprising modifying the second lenslet to include a second corrective feature, the second corrective feature defining a first corrected portion of the second aperture and reducing a transmittance of the operating wavelength through the second lenslet.

Aspect 32 of the description is:
The method of aspect 31, wherein the first corrective feature modifies the centroid of the angular distribution of the light field at the imaging plane and the second corrective feature counteracts the modification to the centroid of the angular distribution of the light field produced by the first corrective feature.

Those skilled in the art will appreciate that the methods and designs described above have additional applications and that the relevant applications are not limited to those specifically recited above. Also, the present invention may be embodied in other specific forms without departing from the essential characteristics as described herein. The embodiments described above are to be considered in all respects as illustrative only and not restrictive in any manner.

What is claimed is:

1. A light homogenizing element comprising:
a lens array configured to transmit light at an operating wavelength, the lens array comprising a plurality of lenslets, the plurality of lenslets including a first lenslet, the first lenslet having a first aperture, the first aperture having a surface with a corrected portion defined by a first corrective feature, the first corrective feature reducing a transmittance of the operating wavelength through the first lenslet.

2. The light homogenizing element of claim 1, wherein each of the plurality of lenslets has a square cross-section.

3. The light homogenizing element of claim 1, wherein the surface of the first aperture is powered.

4. The light homogenizing element of claim 1, wherein the first corrective feature partially covers the surface of the first aperture.

5. The light homogenizing element of claim 1, wherein the first corrective feature is spaced apart from the surface of the first aperture.

6. The light homogenizing element of claim 1, wherein the first corrective feature is a mask.

7. The light homogenizing element of claim 6, wherein the mask is perforated.

8. The light homogenizing element of claim 1, wherein the first corrective feature is translucent.

9. The light homogenizing element of claim 1, wherein the plurality of lenslets further includes a second lenslet, the second lenslet having a second aperture, the second aperture having a surface with a corrected portion defined by a second corrective feature, the second corrective feature reducing a transmittance of the operating wavelength through the second lenslet.

10. The light homogenizing element of claim 9, wherein the second corrective feature is complementary to the first corrective feature.

11. A light illumination system comprising:
a light source;
a first lens array operatively coupled to the light source, the first lens array configured to transmit light at an operating wavelength, the first lens array comprising a plurality of lenslets, the plurality of lenslets including a first lenslet, the first lenslet having a first aperture, the first aperture having a surface with a corrected portion defined by a first corrective feature, the first corrective feature reducing a transmittance of the operating wavelength through the first lenslet.

12. The light illumination system of claim 11, wherein the light source comprises a plurality of light emitting diodes.

13. The light illumination system of claim 12, further comprising a second lens array operatively coupled to the first lens array, the second lens array lacking a corrective feature.

14. The light illumination system of claim 13, wherein the first lens array is positioned between the light source and the second lens array.

15. The light illumination system of claim 14, wherein the light illumination system produces a light field at an imaging plane, the light field having a distribution of irradiance in the imaging plane, the distribution having an average irradiance, a maximum irradiance and a minimum irradiance; and wherein the maximum irradiance differs from the minimum irradiance by less than 10% of the average irradiance.

16. The light illumination system of claim 14, wherein the plurality of lenslets further includes a second lenslet, the second lenslet having a second aperture, the second aperture having a surface with a corrected portion defined by a second corrective feature, the second corrective feature reducing a transmittance of the operating wavelength through the second lenslet.

17. The light illumination system of claim 16, wherein the first corrective feature and the second corrective feature are symmetrically disposed about the center of a pupil of the light illumination system.

18. A method of correcting an illumination system comprising:
producing a light field at an image plane of an illumination system, the illumination system comprising a light source producing light at an operating wavelength, the light source operatively coupled to a first lens array, the first lens array comprising a plurality of lenslets, the plurality of lenslets including a first lenslet and a second lenslet, the first lenslet having a first aperture and the second lenslet having a second aperture;
determining a uniformity of the light field at the image plane by measuring the irradiance of the light field at a plurality of locations in the image plane; and
improving the uniformity of the light field, the improving including modifying the first lenslet to include a first corrective feature, the first corrective feature defining a first corrected portion of the first aperture and reducing a transmittance of the operating wavelength through the first lenslet.

19. The method of claim 18, wherein the distribution of irradiance including a maximum irradiance and a minimum irradiance and the improving includes reducing the difference between the maximum irradiance and the minimum irradiance.

20. The method of claim 18, further comprising:
modifying the second lenslet to include a second corrective feature, the second corrective feature defining a first corrected portion of the second aperture and reducing a transmittance of the operating wavelength through the second lenslet;
wherein the first corrective feature modifies the centroid of the angular distribution of the light field at the imaging plane and the second corrective feature counteracts the modification to the centroid of the angular distribution of the light field produced by the first corrective feature.
